(19) United States
(12) Patent Application Publication
(10) Pub. No.: US 2025/0383375 A1
(43) Pub. Date: Dec. 18, 2025

(54) TRACEABILITY DEVICE FOR DIRECT-CURRENT (DC) HIGH-VOLTAGE DIVIDER BASED ON DISTRIBUTED SYNCHRONOUS MEASUREMENT, AND CALIBRATION METHOD USING THE SAME

(71) Applicant: NATIONAL INSTITUTE OF METROLOGY, CHINA, Beijing (CN)

(72) Inventors: Jiafu WANG, Beijing (CN); Haiming SHAO, Beijing (CN); Huanghui ZHANG, Beijing (CN); Shugen ZHOU, Beijing (CN); Chuansheng LI, Beijing (CN); Lixin WANG, Beijing (CN); Kun WANG, Beijing (CN)

(21) Appl. No.: 19/303,704

(22) Filed: Aug. 19, 2025

Related U.S. Application Data
(63) Continuation of application No. PCT/CN2024/096532, filed on May 31, 2024.

(30) Foreign Application Priority Data
Aug. 21, 2023 (CN) 202311053109.7

(51) Int. Cl. G01R 15/04; G01R 19/25; G01R 35/00; G06F 9/445

(52) U.S. Cl. CPC G01R 15/04; G01R 19/25; G01R 35/005; G06F 9/44505

(57) ABSTRACT

A direct-current (DC) high-voltage divider traceability device based on distributed synchronous measurement, including a standard voltage divider group, a DC voltage distributed synchronous measurement device and a power supply. The standard voltage divider group includes at least two standard DC high-voltage dividers connected in series. A total rated voltage of the series-connected standard DC high-voltage dividers is not less than a rated voltage of a target DC high-voltage divider. The DC voltage distributed synchronous measurement device includes at least three voltage acquisition modules. The power supply is configured to apply an operating voltage at two ends of the standard voltage divider group. The operating voltage is not greater than the total rated voltage of the series-connected standard DC high-voltage dividers. A DC high-voltage divider calibration method using such DC high-voltage divider traceability device is also provided.

### CROSS-REFERENCE TO RELATED APPLICATIONS

This application is a continuation of International Patent Application No. PCT/CN2024/096532, filed on May 31, 2024, which claims the benefit of priority from Chinese Patent Application No. 202311053109.7, filed on Aug. 21, 2023. The content of the aforementioned application, including any intervening amendments thereto, is incorporated herein by reference in its entirety.

### TECHNICAL FIELD

This application relates to calibration of direct-current high-voltage dividers, and more particularly to a traceability device for a direct-current (DC) high-voltage divider based on distributed synchronous measurement, and a calibration method using the same.

### BACKGROUND

A direct current (DC) high-voltage divider is a standard instrument for on-site measurement, including a voltage divider and a measuring instrument. The voltage divider adopts a balanced equipotential shielding structure with high-quality electronic components encapsulated within a fully sealed insulating cylinder, thereby achieving accurate measurement, high linearity and stable performance. The DC high-voltage divider can proportionally attenuate a high DC voltage into a lower DC voltage suitable for direct measurement using electrical instruments.

DC high voltage has been widely used in daily life, industrial production and scientific research. For example, televisions and some lighting devices often rely on the DC high voltage for operation; and for electric vehicles and charging facilities, the DC high voltage can significantly reduce the charging time. In addition, the DC high voltage is also necessary in the chemical industry, such as electrochemical reactions, large-scale particle accelerators, electron colliders, and nuclear fusion devices. To ensure the effective use of DC high voltage, accurate and standardized voltage measurement is essential.

With the development of ultra-high-voltage DC transmission projects in China, there is an urgent demand for measurement and calibration methods and instruments suitable for higher voltage levels. DC high-voltage dividers are widely used for DC high-voltage measurement. To ensure the accuracy of measurements performed by DC high-voltage dividers, it is necessary to accurately calibrate a voltage-division ratio of the DC high-voltage divider (also referred to as tracing the voltage-division ratio of the DC high-voltage divider). Currently, several methods are available for accurately calibrating the voltage-division ratio of DC high-voltage dividers.

### (1) Step-Up method

The step-up method involves measuring voltage-division ratios of two voltage dividers individually and their series combination under the same voltage, and calculating voltage coefficient of the voltage divider based on the voltage coefficients of the high-voltage arm resistors of the two voltage dividers. However, this method requires the high-voltage power supply to maintain highly stable operation during measurement. With increasing voltage levels, ensuring power supply stability becomes progressively more difficult, thereby introducing measurement uncertainty components attributable to voltage fluctuations.

### (2) Leakage Current Method

The leakage current method utilizes a synchronous acquisition system based on fiber-optic or wireless communication to measure the current flowing into the high-voltage arm and the current flowing out of the low-voltage arm, and calculates the leakage current of the voltage divider based on the difference between the two. As the voltage level increases, leakage becomes a primary factor affecting the voltage coefficient of the voltage-division ratio, allowing the voltage coefficient to be evaluated through the measured leakage current. However, this method exhibits low calibration accuracy for the voltage-division ratio at 1000 kV and is incapable of measuring or evaluating the influence of corona current.

### (3) Voltage Addition Method

The voltage addition method uses two auxiliary DC voltage dividers that can be connected in series. Two comparison tests are performed on the main voltage divider at a voltage of U/2 using the auxiliary dividers separately, followed by a comparison test at a voltage of U with the auxiliary dividers connected in series. This enables determination of the voltage coefficient representing the change in the voltage division ratio of the main voltage divider from U/2 to U. However, this method requires specially designed auxiliary voltage dividers and involves complex and inconvenient operation.

In summary, existing DC high-voltage divider calibration methods do not allow for direct calibration of high-voltage-level dividers using the comparison method. For example, when the target DC high-voltage divider is rated at 1000 kV while the available standard DC high-voltage divider on site is rated at only 500 kV, it is not possible to directly calibrate the high-voltage target divider using the lower-voltage standard divider by means of the comparison method.

### SUMMARY

An object of the disclosure is to provide a direct current (DC) high-voltage divider traceability device based on distributed synchronous measurement and a DC high-voltage divider calibration method, so as to solve the problem that a high-voltage-level DC voltage divider cannot be directly calibrated using a comparison method with a low-voltage-level standard DC high-voltage divider during calibration.

Technical solutions of the present disclosure are described as follows.

In a first aspect, this application provides a DC high-voltage divider traceability device based on distributed synchronous measurement, comprising:
a standard voltage divider group;
a DC voltage distributed synchronous measurement device; and
a power supply;
wherein the standard voltage divider group comprises at least two standard DC high-voltage dividers connected in series; and a total rated voltage of the at least two standard DC high-voltage dividers connected in series is not less than a rated voltage of a target DC high-voltage divider;
the DC voltage distributed synchronous measurement device comprises at least three voltage acquisition modules; and one of the at least three voltage acquisition modules is connected to two ends of a low-voltage arm of the target DC high-voltage divider to acquire a secondary output voltage of the target DC high-voltage divider, and remaining voltage acquisition modules of the at least three voltage acquisition modules are connected to two ends of low-voltage arms of the at least two standard DC high-voltage dividers in one-to-one correspondence, so as to synchronously acquire secondary output voltages of the at least two standard DC high-voltage dividers; and
the power supply is configured to apply an operating voltage at two ends of the standard voltage divider group; and the operating voltage is not greater than the total rated voltage of the at least two standard DC high-voltage dividers connected in series.

In a second aspect, this application provides a DC high-voltage divider calibration method using the DC high-voltage divider traceability device described above, comprising:
(S1) connecting two ends of the standard voltage divider group in parallel with the target DC high-voltage divider to form a voltage divider combination; grounding one end of the voltage divider combination; and connecting the power supply to the two ends of the standard voltage divider group;
(S2) activating the DC high-voltage divider traceability device and powering on the host computer; selecting, via the host computer, the at least three voltage acquisition modules from the DC voltage distributed synchronous measurement device; and setting an internet protocol (IP) address of each of the at least three voltage acquisition modules;
(S3) transmitting, via the router, a self-checking command from the host computer to each of the at least three voltage acquisition modules; performing, by each of the at least three voltage acquisition modules, self-checking in response to the self-checking command; and
(S4) performing a calibration main cycle process;
wherein the calibration main cycle process is performed through steps of:
applying, by the power supply, a voltage to the at least two standard DC high-voltage dividers connected in series;
synchronously acquiring, by the at least three voltage acquisition modules, the secondary output voltages of the at least two standard DC high-voltage dividers;
remotely transmitting the secondary output voltages of the at least two standard DC high-voltage dividers to the host computer; and
calculating, by the host computer, a voltage division ratio of the target DC high-voltage divider.

Compared to the prior art, the present disclosure has the following beneficial effects.
(1) Regarding the traceability device provided herein, the standard voltage divider group includes at least two standard DC high-voltage dividers connected in series. By means of this configuration, a DC high-voltage divider with a distributed low-voltage arm structure is formed. This enables the use of a comparison method to directly calibrate a high-voltage-level target DC high-voltage divider using standard DC high-voltage dividers of lower-voltage levels, thereby simplifying the calibration process. Compared with conventional methods such as the step-up method and the voltage addition method, the present disclosure eliminates the need for a high-accuracy high-voltage power supply and does not require any special auxiliary voltage dividers.
(2) By means of the DC high-voltage divider having a distributed low-voltage arm structure formed by at least two standard DC high-voltage dividers connected in series, the present disclosure enables wireless synchronized measurement of voltages across two ends of each low-voltage arm. In combination with the known resistance values of the low-voltage arms, the current flowing through each low-voltage arm can be calculated, thereby allowing a quantitative evaluation of the impact caused by leakage current on the voltage division ratio. Compared with conventional DC high-voltage dividers, the present disclosure can further improve the accuracy of voltage division ratio measurement.
(3) By means of voltage acquisition modules with wireless synchronized acquisition capability, the input voltage signal is processed by a signal conditioning circuit, which performs filtering, buffering, and attenuation. A second-order low-pass filter is used to eliminate alternating current (AC) signals and noise, allowing only the required DC voltage signal to pass through. The use of wireless synchronization enables the voltages across the low-voltage arms to be measured simultaneously, thereby minimizing the impact of ripple and drift from the high-voltage power supply. Additionally, lithium battery power is adopted to enhance electrical safety during measurement. These features collectively ensure high accuracy in measuring the secondary output voltage of the voltage divider and significantly improve the precision of the voltage division ratio measurement.

The above description is merely a summary of the technical solutions of the present disclosure. To better understand the technical solutions adopted by the present disclosure and to implement the disclosure accordingly, as well as to make the above and other objects, features, and advantages of the disclosure more apparent and comprehensible, specific embodiments of the present disclosure are described in detail below.

### BRIEF DESCRIPTION OF THE DRAWINGS

The following provides a further description of the present disclosure with reference to the accompanying drawings and the embodiments.

FIG. 1 is a block diagram of a system including a direct-current (DC) high-voltage divider traceability device based on distributed synchronous measurement according to an embodiment of the present disclosure and a host computer;

FIG. 2 is an overall structural diagram of the DC high-voltage divider traceability device according to an embodiment of the present disclosure;

FIG. 3 is a structural diagram of a standard voltage divider group according to an embodiment of the present disclosure;

FIG. 4 is a block diagram of a DC voltage distributed synchronous measurement device according to an embodiment of the present disclosure;

FIG. 5 is a structural diagram of a power supply module according to an embodiment of the present disclosure;

FIG. 6 is a flow chart of a voltage acquisition process according to an embodiment of the present disclosure;

FIG. 7 is a flow chart of a DC high-voltage divider calibration method according to an embodiment of the present disclosure; and

FIG. 8 is a flow chart of an execution process of the host computer during calibration according to an embodiment of the present disclosure.

### DETAILED DESCRIPTION OF EMBODIMENTS

According to embodiments of the present disclosure, a direct-current (DC) high-voltage divider traceability device based on distributed synchronous measurement and a DC high-voltage divider calibration method are provided, so as to solve the problem that a high-voltage-level divider cannot be directly calibrated using a comparison method with a low-voltage-level standard DC high-voltage divider during calibration.

As used herein, the term “high voltage” refers to a voltage equal to or greater than 1 kV.

The technical solution of the embodiment of the present disclosure is generally as follows. To address the issue that a high-voltage-level DC high-voltage divider cannot be directly calibrated using the comparison method, a DC high-voltage divider traceability device based on distributed synchronous measurement and a DC high-voltage divider calibration method are provided. The distributed synchronous measurement-based DC high-voltage divider of the present disclosure includes multiple sections of high-voltage arms and low-voltage arms, which are configured to be separable and support wireless synchronous acquisition of secondary output voltages under high-voltage conditions. In the DC high-voltage divider calibration method, two ends of a standard voltage divider group in the distributed synchronous measurement-based DC high-voltage divider are connected in parallel with a target DC high-voltage divider to form a voltage divider combination, and one end of the voltage divider combination is grounded. A power supply is connected to the two ends of the standard voltage divider group. This configuration enables a system including the DC high-voltage divider traceability device and a host computer to synchronously measure voltages at two ends of each low-voltage arm in the standard voltage divider group, thereby achieving accurate measurement of high DC voltages and precise calibration of a voltage division ratio of the DC high-voltage divider.

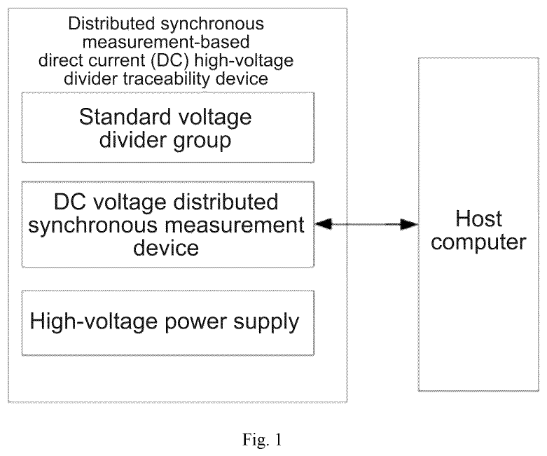

Before describing the embodiments, the system corresponding to the method of the present disclosure is first introduced. As shown in FIG. 1, the system includes the DC high-voltage divider traceability device and the host computer.

The DC high-voltage divider traceability device includes a standard voltage divider group, a DC voltage distributed synchronous measurement device, and the power supply. The standard voltage divider group is connected in parallel with a target DC high-voltage divider.

The power supply is configured to apply an operating voltage at two ends of the standard voltage divider group. The DC voltage distributed synchronous measurement device is configured to synchronously acquire secondary output voltage of the standard voltage divider group and perform signal processing.

The host computer is configured to receive the signal-processed secondary output voltage and calculate a voltage division ratio of the target DC high-voltage divider, thereby completing calibration of the target DC high-voltage divider.

### Example 1

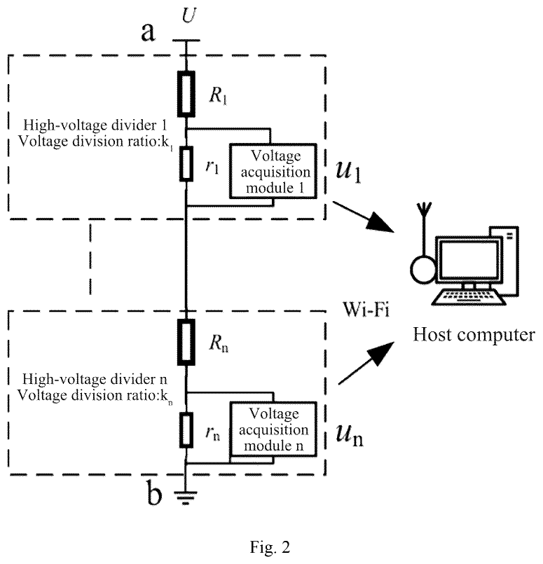

As shown in FIG. 2, in this embodiment, a DC high-voltage divider traceability device based on distributed synchronous measurement is provided. The DC high-voltage divider traceability device includes a standard voltage divider group, a DC voltage distributed synchronous measurement device, and a power supply.

The standard voltage divider group includes at least two standard DC high-voltage dividers connected in series. A total rated voltage of the at least two standard DC high-voltage dividers connected in series is not less than a rated voltage of a target DC high-voltage divider, so as to prevent the at least two standard DC high-voltage dividers and the target DC high-voltage divider from being damaged due to an overvoltage input.

The DC voltage distributed synchronous measurement device includes at least three voltage acquisition modules. One of the at least three voltage acquisition modules is connected to two ends of a low-voltage arm of the target DC high-voltage divider to acquire a secondary output voltage of the target DC high-voltage divider, and remaining voltage acquisition modules of the at least three voltage acquisition modules are connected to two ends of low-voltage arms of the at least two standard DC high-voltage dividers in one-to-one correspondence, so as to synchronously acquire secondary output voltages of the at least two standard DC high-voltage dividers.

The power supply is configured to apply an operating voltage at two ends of the standard voltage divider group. The operating voltage is not greater than the total rated voltage of the at least two standard DC high-voltage dividers connected in series.

Taking a standard voltage divider group formed by two standard DC high-voltage dividers of the same specification connected in series as an example, a principle of the direct calibration method based on a comparison method according to the present disclosure is as follows.

Under ideal conditions, a voltage division ratio of each of the two series- connected standard DC high-voltage dividers is kₐ, and a rated voltage of each of the two standard DC high-voltage dividers is U. Using such a configuration of the standard voltage divider group allows calibration of a to-be-tested divider having a rated operating voltage of 2U, i.e., a maximum voltage that can be applied across terminals a and b is 2U.

As shown in FIG. 2, taking the standard voltage divider group formed by two standard DC high-voltage dividers of the same specification connected in series as an example, in the standard voltage divider group, a high-voltage arm R₁ and a low-voltage arm r₁ form a first standard DC high-voltage divider, and a high-voltage arm R₂ and a low-voltage arm r₂ form a second standard DC high-voltage divider. The two dividers are standard DC high-voltage dividers of the same specification, and under ideal conditions, R₁=R₂ and r₁=r₂.

A DC high voltage generated by a high-voltage generator is applied across the two standard DC high-voltage dividers connected in series. A first voltage acquisition module and a second voltage acquisition module are powered by batteries, and are configured to wirelessly transmit voltages across r₁ and r₂ to a host computer via a wireless fidelity (Wi-Fi) module. At this time, an input voltage U is expressed as:

$$U = {k}_{1} {u}_{1} + {k}_{2} {u}_{2} .$$

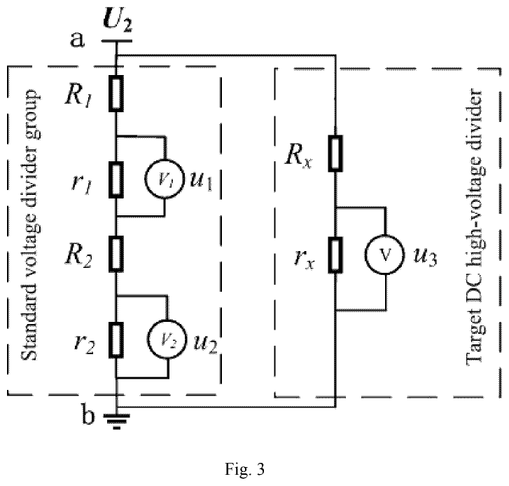

As shown in FIG. 3, the two standard DC high-voltage dividers of the same specification are referred to as the first standard DC high-voltage divider and the second standard DC high-voltage divider. When a voltage U₂ is applied across the terminals a and b, for the combined voltage divider (formed by the first standard DC high-voltage divider and the second standard DC high-voltage divider connected in series), a primary-side voltage is U_{2,} and a secondary-side voltage is (u₁+u₂), the voltage U₂ is expressed as:

$${U}_{2} = {k}_{a} ( {u}_{1} + {u}_{2} ) .$$

Accordingly, a voltage division ratio of the combined voltage divider can be expressed as:

$$k = \frac{{U}_{2}}{{u}_{1} + {u}_{2}} = \frac{{k}_{a} ( {u}_{1} + {u}_{2} )}{{u}_{1} + {u}_{2}} .$$

A voltage division ratio of the to-be-tested voltage divider can be determined as:

$${k}_{3} = \frac{{U}_{2}}{{u}_{3}} = \frac{{k}_{a} ( {u}_{1} + {u}_{2} )}{{u}_{3}} .$$

However, in practice, the voltage division ratios of the two standard DC high-voltage dividers are difficult to match perfectly. Therefore, individual calibration is required. After calibration, the voltage division ratios of the two standard dividers are k₁ and k₂, respectively. Under this condition, the voltage division ratio k of the to-be-tested voltage divider is calculated as:

$$k = \frac{{U}_{2}}{{u}_{3}} = \frac{{k}_{1} {u}_{1} + {k}_{2} {u}_{2}}{{u}_{3}} .$$

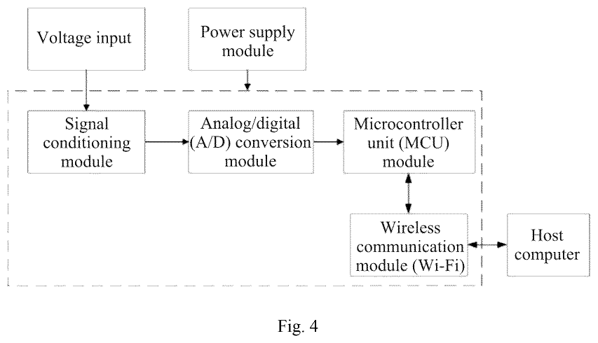

As shown in FIG. 4, in order to obtain the voltage division ratio of the to-be-tested voltage divider, it is necessary to measure the secondary output voltage of the two standard DC high-voltage dividers. The present disclosure provides a DC voltage distributed synchronous measurement device, which includes at least three voltage acquisition modules. One of the at least three voltage acquisition modules is configured to acquire a secondary output voltage of the target DC high-voltage divider, and remaining voltage acquisition modules of the at least three voltage acquisition modules are configured to acquire secondary output voltages of the two standard DC high-voltage dividers.

Each of the at least three voltage acquisition modules includes a signal conditioning circuit, an analog/digital (A/D) conversion circuit, a microcontroller unit (MCU) control module, a wireless communication module, and a power supply module. The signal conditioning circuit, the A/D conversion circuit, the MCU control module, and the wireless communication module are connected in sequence. The power supply module is configured to supply power to the signal conditioning circuit, the A/D conversion circuit, the MCU control module and the wireless communication module.

The signal conditioning circuit is configured to receive an input signal corresponding to the secondary output voltages of a corresponding one of the two standard DC high-voltage dividers, and retain a DC voltage signal by filtering out alternating current (AC) signals and noise from the input signal.

The A/D conversion circuit is configured to perform analog-to-digital conversion on the DC voltage signal to obtain a converted voltage signal.

The MCU control module is configured to transmit the converted voltage signal to the host computer via the wireless communication module and to respond to a synchronous acquisition control command from the host computer.

The wireless communication module is configured to enable data transmission between the MCU control module and the host computer, so as to achieve synchronous acquisition of the secondary output voltages of the at least two standard DC high-voltage dividers in the standard voltage divider group.

In the present disclosure, the wireless communication module may employ Wi-Fi communication technology to achieve wireless synchronous acquisition of voltage data, thereby reducing the impact of ripple and drift of the DC high-voltage source on measurement accuracy.

To prevent damage to the voltage acquisition modules caused by local tip discharge, the one of the at least three voltage acquisition modules is provided within a grading ring of the target DC high-voltage divider, and the remaining voltage acquisition modules of the at least three voltage acquisition modules are provided within grading rings of the two standard DC high-voltage dividers in one-to-one correspondence.

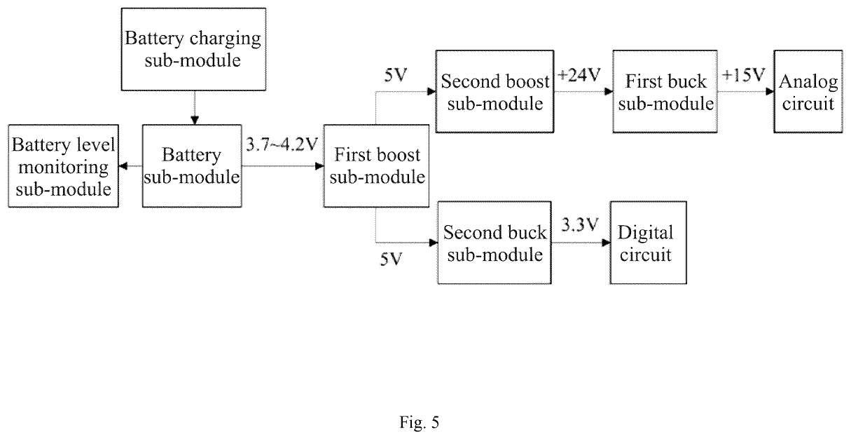

As shown in FIG. 5, the power supply module includes a battery sub-module, a first boost sub-module, an analog circuit power supply branch, a digital circuit power supply branch, a battery level monitoring sub-module and a battery charging sub-module. The battery sub-module is connected to the analog circuit power supply branch and the digital circuit power supply branch via the first boost sub-module. The battery sub-module is further connected to the battery level monitoring sub-module and the battery charging sub-module.

The analog circuit power supply branch includes a second boost sub-module and a first buck sub-module.

The digital circuit power supply branch includes a second buck sub-module.

The battery sub-module is configured to output a voltage within a range of 3.7-4.2V. The first boost sub-module is configured to boost the voltage output from the battery sub-module to 5V and transmit the 5V voltage to the second boost sub-module and the second buck sub-module. The second boost sub-module is configured to boost the 5 V voltage to 20 V, and the first buck sub-module is configured to reduce the 20 V voltage to 15 V to power an analog circuit sub-module. The second buck sub-module is configured to reduce the 5 V voltage to 3.3 V to power a digital circuit sub-module. The design in which the voltage is first boosted and then reduced is effective in suppressing ripple and enhancing the precision of the power supply.

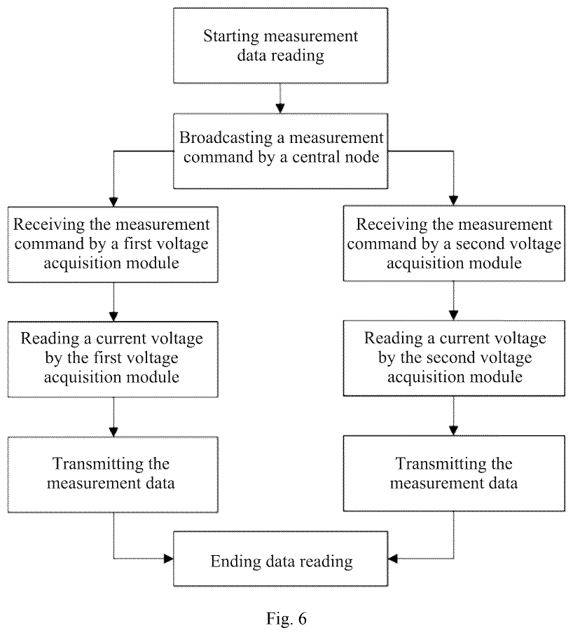

To ensure the safety of both the equipment and the operator when the voltage acquisition modules are used under high-voltage conditions, wireless communication with the host computer is employed. In the present disclosure, the wireless communication module is a USR-C216 serial port Wi-Fi module (Jinan USR IOT Technology Co., Ltd.), which enables wireless data interaction between a sampling device and the host computer. The wireless communication module is communicated with external devices through a serial interface to realize wireless network connection and data transmission. As shown in FIG. 6, to reduce the impact of ripple and drift from the high-voltage source on measurement accuracy, multiple voltage acquisition modules are used to synchronously measure the secondary output voltages of two standard DC high-voltage dividers. The wireless communication module uses Wi-Fi technology to enable data transmission between the MCU and the host computer, with a typical transmission delay on the order of milliseconds. Each of the at least three voltage acquisition modules, a router and the host computer form a node network. The at least three voltage acquisition modules are connected to the host computer through the router as a central node. The central node is configured to transmit measurement commands for the secondary output voltages of the at least two standard DC high-voltage dividers via broadcasting. The host computer is configured to acquire voltage data via the central node.

When distances between the two voltage acquisition modules and the router are less than 10 meters, the first voltage acquisition module and the second voltage acquisition module can be considered to receive the measurement instruction simultaneously under normal communication conditions. The two voltage acquisition modules transmit the acquired voltage values to the central node of the host computer. The time difference throughout the measurement process is on the order of milliseconds, during which the fluctuation in the output voltage of the high-voltage power supply is less than 10⁻⁶. Therefore, the two voltage acquisition modules can be considered to achieve approximately synchronous sampling.

It should be noted that the at least two standard DC high-voltage dividers in the standard voltage divider group may be either of the same specification or of different specifications. However, it is required that the total rated voltage of the at least two standard DC high-voltage dividers connected in series in the standard voltage divider group be not less than the rated voltage of the target DC high-voltage divider. Moreover, after the power supply is switched on, the operating voltage applied at two ends of each of the at least two standard DC high-voltage dividers in the standard voltage divider group is not greater than its rated voltage.

### Example 2

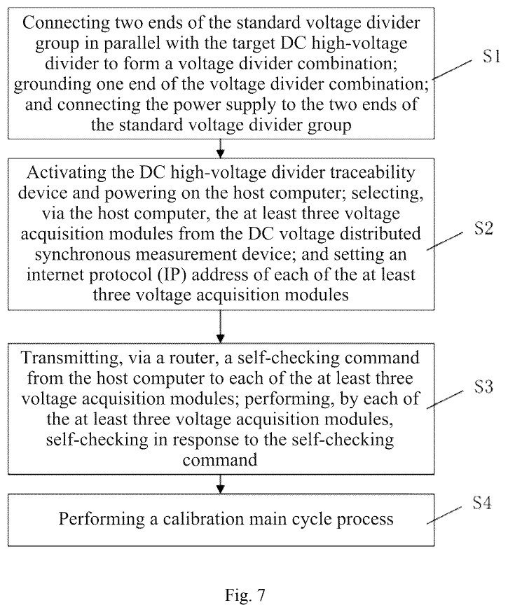

As shown in FIG. 7, provided herein is a DC high-voltage divider calibration method using the DC high-voltage divider traceability device described in Example 1, including the following steps.

(S1) Two ends of the standard voltage divider group are connected in parallel with the target DC high-voltage divider to form a voltage divider combination, and then one end of the voltage divider combination is grounded. The power supply is connected to the two ends of the standard voltage divider group.

The at least two standard DC high-voltage dividers in the standard voltage divider group may be of the same specification or of different specifications. However, it is required that the total rated voltage of the at least two standard DC high-voltage dividers connected in series be not less than the rated voltage of the target DC high-voltage divider. In addition, after the power supply is turned on, the operating voltage applied at two ends of each of the at least two standard DC high-voltage dividers in the standard voltage divider group is not greater than its rated voltage.

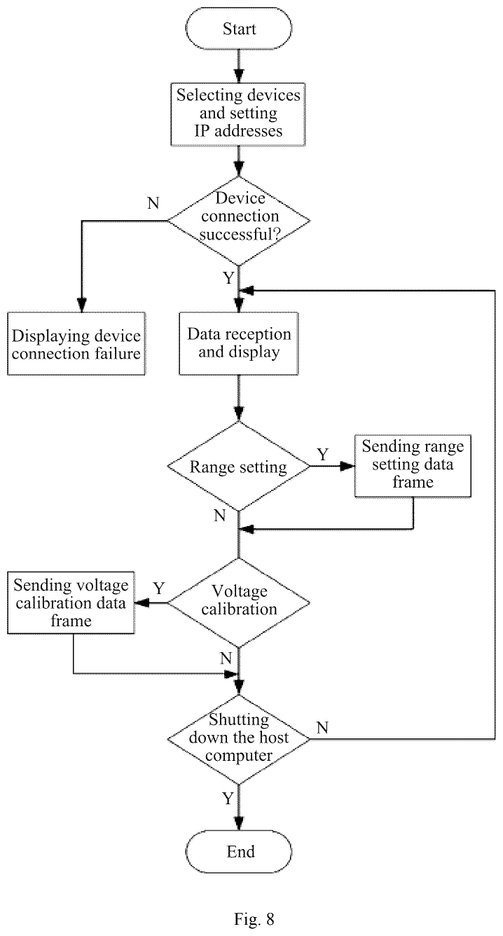

(S2) As shown in FIG. 8, the system is powered on and started. The at least three voltage acquisition modules are selected via the host computer from the DC voltage distributed synchronous measurement device. An Internet Protocol (IP) address of each of the at least three voltage acquisition modules is set.

(S3) A self-checking command is transmitted from the host computer to each of the at least three voltage acquisition modules via the router. Self-checking is performed by each of the at least three voltage acquisition modules in response to the self-checking command.

If no response is received from the at least three voltage acquisition modules, a connection failure is indicated, and a prompt is provided for manual inspection of the system.

(S4) A calibration main cycle process is performed.

The calibration main cycle process is performed through the following steps. A voltage is applied by the power supply to the at least two standard DC high-voltage dividers connected in series. The secondary output voltages of the at least two standard DC high-voltage dividers are synchronously acquired by the at least three voltage acquisition modules and transmitted remotely to the host computer. A voltage division ratio of the target DC high-voltage divider is then calculated by the host computer.

Since the voltage division ratios of the standard DC high-voltage dividers in the standard voltage divider group are unlikely to be identical, each of the standard DC high-voltage dividers is required to be individually calibrated in advance. Specifically, each of the at least two standard DC high-voltage dividers in the standard voltage divider group is pre-calibrated through the following steps.

An ordinary DC high-voltage divider is selected in sequence as a to-be-tested voltage divider X. A voltage division ratio of the to-be-tested voltage divider X is k_{X}, where X=1, 2, 3, . . . , n, and n is the number of the at least two standard DC high-voltage dividers in the standard voltage divider group, and n≥2.

A calibrated standard DC high-voltage divider Y is connected in parallel with the to-be-tested voltage divider X across terminals a and b.

A stable high-voltage power supply output U is applied across the terminals a and b, such that a primary-side voltage of the standard DC high-voltage divider Y and a primary-side voltage of the to-be-tested voltage divider X are both U. A secondary-side voltage of the standard DC high-voltage divider Y and a secondary-side voltage of the to-be-tested voltage divider X are measured using two digital voltmeters with synchronous triggering functions. The voltage division ratio k_{X} of the to-be-tested voltage divider X is calculated, expressed as:

$${k}_{X} = \frac{{k}_{0} {u}_{0}}{{u}_{X}} .$$

In the above equation, k₀ is a voltage division ratio of the standard DC high-voltage divider Y, u₀ is the secondary-side voltage of the standard DC high-voltage divider Y, and u_{X} is the secondary-side voltage of the to-be-tested voltage divider X.

A computer program executed by the host computer is configured to calculate a current flowing into and out of a next standard DC high-voltage divider based on a secondary-side voltage to evaluate an impact caused by leakage current through the following steps.

The standard voltage divider group is divided into a first-section voltage divider group and a second-section voltage divider group using an insulating frame. (In general, a voltage divider is provided with an insulating frame (also referred to as insulating housing). The insulating frame is filled with insulating oil. The first-section voltage divider group refers to the part exposed to the high-voltage terminal. The two sections division enables a quantitative analysis of leakage current, i.e., the current flowing through the insulating frame.)

A relative leakage current is determined. And the relative leakage current is a relative current difference, expressed as:

$$\frac{Δ I}{I} = \frac{{I}_{in} - {I}_{out}}{{I}_{out}} .$$

In the above equation, Iᵢₙ is a current input into the first-section voltage divider group, and Iₒᵤₜ is a current input into the second-section voltage divider group during calibration test.

A theoretical voltage V_{HV} across two ends of the second-section voltage divider group is determined as:

$${V}_{HV} \approx \frac{{I}_{in} + {I}_{out}}{2} ( {R}_{i} + {R}_{i + 1} + … + {R}_{n} + {r}_{i} + {r}_{i + 1} + … + {r}_{n} ) .$$

In the above equation, i indicates that the insulating frame is provided above an i-th standard DC high-voltage divider in the standard voltage divider group; Rᵢ, Rᵢ₊₁, . . . , Rₙ are high-voltage arm resistances of the second-section voltage divider group; and rᵢ, rᵢ₊₁, . . . , rₙ are low-voltage arm resistances of the second-section voltage divider group.

In actual measurement, a voltage across the second-section voltage divider group is determined as follows:

$${V}_{HVM} = {I}_{out} ( {R}_{i} + {R}_{i + 1} + … + {R}_{n} + {r}_{i} + {r}_{i + 1} + … + {r}_{n} ) .$$

A voltage deviation ΔV caused by the leakage current is determined as:

$$ΔV = {V}_{HVM} - {V}_{HV} \approx {I}_{out} ( {R}_{i} + {R}_{i + 1} + … + {R}_{n} + {r}_{i} + {r}_{i + 1} + … + {r}_{n} ) - \frac{{I}_{in} + {I}_{out}}{2} ( {R}_{i} + {R}_{i + 1} + … + {R}_{n} + {r}_{i} + {r}_{i + 1} + … + {r}_{n} ) .$$

A measured total voltage of low-voltage arms in the first-section voltage divider group is defined as u_{first}, a measured total resistance of the low-voltage arms in the first-section voltage divider group is defined as r_{first}, a measured total voltage of low-voltage arms in the second-section voltage divider group is defined as u_{second}, and a measured total resistance of the low-voltage arms in the second-section voltage divider group is defined as r_{second}. Then, a relative voltage error φ is determined as:

$$φ = \frac{ΔV}{V} = \frac{ΔV}{{V}_{HVM}} \approx \frac{{I}_{out} - {I}_{in}}{2 {I}_{out}} = \frac{\frac{{u}_{second}}{{r}_{second}} - \frac{{u}_{first}}{{r}_{first}}}{2 \frac{{u}_{second}}{{r}_{second}}} = \frac{1}{2} ( 1 - \frac{{u}_{first} {r}_{second}}{{u}_{second} {r}_{first}} ) .$$

The impact caused by the leakage current is quantitatively analyzed through the following step. Considering that the relative voltage error φ caused by the leakage current is always negative, the measured total voltage u_{second} is corrected according to the following formula:

$${u}_{corrected} = {u}_{second} \times ( 1 - φ ) .$$

In the above equation, u_{corrected}is a corrected value of the u_{second}.

As shown in FIG. 8, the calibration main cycle process includes a data reception and display node, a range setting node, a voltage calibration node, a data storage node, and a host computer shutdown node. Each of the data reception and display node, the range setting node, the voltage calibration node, the data storage node and the host computer shutdown node is provided with a corresponding function button for user operation.

In summary, one or more technical solutions provided in the embodiments of the present disclosure offer at least the following technical effects or advantages.
(1) Regarding the traceability device provided herein, the standard voltage divider group includes at least two standard DC high-voltage dividers connected in series. By means of this configuration, a DC high-voltage divider with a distributed low-voltage arm structure is formed. This enables the use of a comparison method to directly calibrate a high-voltage-level target DC high-voltage divider using standard DC high-voltage dividers of lower voltage levels, thereby simplifying the calibration process. Compared with conventional methods such as the step-up method and the voltage addition method, the present disclosure eliminates the need for a high-accuracy high-voltage power supply and does not require any special auxiliary voltage dividers.
(2) By means of the DC high-voltage divider having a distributed low-voltage arm structure formed by at least two standard DC high-voltage dividers connected in series, the present disclosure enables wireless synchronized measurement of voltages across two ends of each low-voltage arm. In combination with the known resistance values of the low-voltage arms, the current flowing through each low-voltage arm can be calculated, thereby allowing a quantitative evaluation of the impact caused by leakage current on the voltage division ratio. Compared with conventional DC high-voltage dividers, the present disclosure can further improve the accuracy of voltage division ratio measurement.
(3) By means of voltage acquisition modules with wireless synchronized acquisition capability, the input voltage signal is processed by a signal conditioning circuit, which performs filtering, buffering, and attenuation. A second-order low-pass filter is used to eliminate alternating current (AC) signals and noise, allowing only the required DC voltage signal to pass through. The use of wireless synchronization enables the voltages across the low-voltage arms to be measured simultaneously, thereby minimizing the impact of ripple and drift from the high-voltage power supply. Additionally, lithium battery power is adopted to enhance electrical safety during measurement. These features collectively ensure high accuracy in measuring the secondary output voltage of the voltage divider and significantly improve the precision of the voltage division ratio measurement.

Described embodiments are merely illustrative, and are not intended to limit the scope of the present disclosure. It should be understood that various modifications, changes and replacements made by those skilled in the art without departing from the spirit of the disclosure shall fall within the scope of the present disclosure defined by the appended claims.

What is claimed is:

1. A direct-current (DC) high-voltage divider traceability device based on distributed synchronous measurement, comprising:
a standard voltage divider group;
a DC voltage distributed synchronous measurement device; and
a power supply;
wherein the standard voltage divider group comprises at least two standard DC high-voltage dividers connected in series; and a total rated voltage of the at least two standard DC high-voltage dividers connected in series is not less than a rated voltage of a target DC high-voltage divider;
the DC voltage distributed synchronous measurement device comprises at least three voltage acquisition modules; and one of the at least three voltage acquisition modules is connected to two ends of a low-voltage arm of the target DC high-voltage divider to acquire a secondary output voltage of the target DC high-voltage divider, and remaining voltage acquisition modules of the at least three voltage acquisition modules are connected to two ends of low-voltage arms of the at least two standard DC high-voltage dividers in one-to-one correspondence, so as to synchronously acquire secondary output voltages of the at least two standard DC high-voltage dividers; and
the power supply is configured to apply an operating voltage at two ends of the standard voltage divider group; and the operating voltage is not greater than the total rated voltage of the at least two standard DC high-voltage dividers connected in series.

2. The DC high-voltage divider traceability device according to claim 1, wherein each of the at least three voltage acquisition modules comprises a signal conditioning circuit, an analog/digital (A/D) conversion circuit, a microcontroller unit (MCU) control module, a wireless communication module and a power supply module;
the signal conditioning circuit, the A/D conversion circuit, the MCU control module and the wireless communication module are connected in sequence; and the power supply module is configured to supply power to the signal conditioning circuit, the A/D conversion circuit, the MCU control module and the wireless communication module;
the signal conditioning circuit is configured to receive an input signal corresponding to a secondary output voltage of a corresponding one of the at least two standard DC high-voltage dividers, and retain a DC voltage signal by filtering out alternating current (AC) signals and noise from the input signal;
the A/D conversion circuit is configured to perform analog-to-digital conversion on the DC voltage signal to obtain a converted voltage signal;
the MCU control module is configured to transmit the converted voltage signal to a host computer via the wireless communication module, and to respond to a synchronous acquisition control command from the host computer; and
the wireless communication module is configured to enable data transmission between the MCU control module and the host computer, so as to achieve synchronous acquisition of the secondary output voltages of the at least two standard DC high-voltage dividers in the standard voltage divider group.

3. The DC high-voltage divider traceability device according to claim 2, wherein the power supply module comprises a battery sub-module, a first boost sub-module, an analog circuit power supply branch, a digital circuit power supply branch, a battery level monitoring sub-module and a battery charging sub-module;
the battery sub-module is connected to the analog circuit power supply branch and the digital circuit power supply branch via the first boost sub-module; and the battery sub-module is further connected to the battery level monitoring sub-module and the battery charging sub-module;
the analog circuit power supply branch comprises a second boost sub-module and a first buck sub-module;
the digital circuit power supply branch comprises a second buck sub-module;
the battery sub-module is configured to output a voltage within a range of 3.7-4.2V;
the first boost sub-module is configured to boost the voltage output from the battery sub-module to 5V and transmit the 5V voltage to the second boost sub-module and the second buck sub-module;
the second boost sub-module is configured to boost the 5 V voltage to 20 V, and the first buck sub-module is configured to reduce the 20 V voltage to 15 V; and
the second buck sub-module is configured to reduce the 5 V voltage to 3.3 V.

4. The DC high-voltage divider traceability device according to claim 2, wherein the wireless communication module is a wireless fidelity (Wi-Fi) module;
the at least three voltage acquisition modules are connected to the host computer through a router as a central node;
the central node is configured to transmit measurement commands for the secondary output voltages of the at least two standard DC high-voltage dividers via broadcasting; and
the host computer is configured to acquire voltage data through the central node.

5. The DC high-voltage divider traceability device according to claim 1, wherein the at least two standard DC high-voltage dividers in the standard voltage divider group have the same specification; and
the one of the at least three voltage acquisition modules is provided within a grading ring of the target DC high-voltage divider; and the remaining voltage acquisition modules of the at least three voltage acquisition modules are provided within grading rings of the at least two standard DC high-voltage dividers in one-to-one correspondence.

6. A DC high-voltage divider calibration method using the DC high-voltage divider traceability device according to claim 4, comprising:
(S1) connecting two ends of the standard voltage divider group in parallel with the target DC high-voltage divider to form a voltage divider combination; grounding one end of the voltage divider combination; and connecting the power supply to the two ends of the standard voltage divider group;
(S2) activating the DC high-voltage divider traceability device and powering on the host computer; selecting, via the host computer, the at least three voltage acquisition modules from the DC voltage distributed synchronous measurement device; and setting an internet protocol (IP) address of each of the at least three voltage acquisition modules;
(S3) transmitting, via the router, a self-checking command from the host computer to each of the at least three voltage acquisition modules; performing, by each of the at least three voltage acquisition modules, self-checking in response to the self-checking command; and
(S4) performing a calibration main cycle process;
wherein the calibration main cycle process is performed through steps of:
applying, by the power supply, a voltage to the at least two standard DC high-voltage dividers connected in series;
synchronously acquiring, by the at least three voltage acquisition modules, the secondary output voltages of the at least two standard DC high-voltage dividers;
remotely transmitting the secondary output voltages of the at least two standard DC high-voltage dividers to the host computer; and
calculating, by the host computer, a voltage division ratio of the target DC high-voltage divider.

7. The calibration method according to claim 6, wherein each of the at least two standard DC high-voltage dividers in the standard voltage divider group is pre-calibrated through steps of:
sequentially selecting an ordinary DC high-voltage divider as a to-be-tested voltage divider X, wherein a voltage division ratio of the to-be-tested voltage divider X is k_{X}; X=1, 2, 3, . . . , n; and n is the number of the at least two standard DC high-voltage dividers in the standard voltage divider group, and n≥2; and
connecting the to-be-tested voltage divider X in parallel with a calibrated standard DC high-voltage divider Y across terminals a and b;
applying a power supply output U across the terminals a and b, such that a primary-side voltage of the standard DC high-voltage divider Y and a primary-side voltage of the to-be-tested voltage divider X are both U; measuring a secondary-side voltage of the standard DC high-voltage divider Y and a secondary-side voltage of the to-be-tested voltage divider X using two digital voltmeters with synchronous triggering functions; and
calculating the voltage division ratio k_{X} of the to-be-tested voltage divider X, expressed as:
$${k}_{X} = \frac{{k}_{0} {u}_{0}}{{u}_{X}} ;$$
wherein k₀ is a voltage division ratio of the standard DC high-voltage divider Y, u₀ is the secondary-side voltage of the standard DC high-voltage divider Y, and u_{X} is the secondary-side voltage of the to-be-tested voltage divider X.

8. The calibration method according to claim 6, wherein a computer program executed by the host computer is configured to calculate a current flowing into and out of a next standard DC high-voltage divider based on a secondary-side voltage to evaluate an impact caused by leakage current through the following steps:
dividing the standard voltage divider group into a first-section voltage divider group and a second-section voltage divider group using an insulating frame;
determining a relative leakage current, wherein the relative leakage current is a relative current difference, expressed as:
$$\frac{Δ I}{I} = \frac{{I}_{in} - {I}_{out}}{{I}_{out}} ;$$
wherein Iᵢₙ is a current input into the first-section voltage divider group, and Iₒᵤₜ is a current input into the second-section voltage divider group during calibration test;
determining a theoretical voltage V_{HV} across two ends of the second-section voltage divider group as:
$${V}_{HV} \approx \frac{{I}_{in} + {I}_{out}}{2} ( {R}_{i} + {R}_{i + 1} + … + {R}_{n} + {r}_{i} + {r}_{i + 1} + … + {r}_{n} ) ;$$
wherein i indicates that the insulating frame is provided above an i-th standard DC high-voltage divider in the standard voltage divider group; Rᵢ, Rᵢ₊₁, . . . , Rₙ are high-voltage arm resistances of the second-section voltage divider group; and rᵢ, rᵢ₊₁, . . . , rₙ are low-voltage arm resistances of the second-section voltage divider group;
determining a voltage across the second-section voltage divider group as follows:
$${V}_{HVM} = {I}_{out} ( {R}_{i} + {R}_{i + 1} + … + {R}_{n} + {r}_{i} + {r}_{i + 1} + … + {r}_{n} ) ;$$
determining a voltage variation ΔV caused by the leakage current as:
$$ΔV = {V}_{HVM} - {V}_{HV} \approx {I}_{out} ( {R}_{i} + {R}_{i + 1} + … + {R}_{n} + {r}_{i} + {r}_{i + 1} + … + {r}_{n} ) - \frac{{I}_{in} + {I}_{out}}{2} ( {R}_{i} + {R}_{i + 1} + … + {R}_{n} + {r}_{i} + {r}_{i + 1} + … + {r}_{n} ) ;$$
defining a measured total voltage of low-voltage arms in the first-section voltage divider group as u_{first}, defining a measured total resistance of the low-voltage arms in the first-section voltage divider group as r_{first}, defining a measured total voltage of low-voltage arms in the second-section voltage divider group as u_{second}, and defining a measured total resistance of the low-voltage arms in the second-section voltage divider group as r_{second},
determining a relative voltage error φ as:
$$φ = \frac{ΔV}{V} = \frac{ΔV}{{V}_{HVM}} \approx \frac{{I}_{out} - {I}_{in}}{2 {I}_{out}} = \frac{\frac{{u}_{second}}{{r}_{second}} - \frac{{u}_{first}}{{r}_{first}}}{2 \frac{{u}_{second}}{{r}_{second}}} = \frac{1}{2} ( 1 - \frac{{u}_{first} {r}_{second}}{{u}_{second} {r}_{first}} ) ;$$
and
quantitatively analyzing the impact caused by the leakage current through a step of:
considering that the relative voltage error φ caused by the leakage current is always negative, correcting the measured total voltage u_{second} according to the following formula:
$${u}_{corrected} = {u}_{second} \times ( 1 - φ ) ;$$
wherein u_{corrected} is a corrected value of the u_{second}.

9. The calibration method according to claim 6, wherein the calibration main cycle process comprises a data reception and display node, a range setting node, a voltage calibration node, a data storage node and a host computer shutdown node; and each of the data reception and display node, the range setting node, the voltage calibration node, the data storage node and the host computer shutdown node is provided with a corresponding function button for user operation.

10. The calibration method according to claim 6, wherein in step (S3), if the host computer does not receive a response from the at least three voltage acquisition modules, it indicates a failed connection, and a warning is generated to prompt manual inspection.
